(19) United States
(12) Patent Application Publication
(10) Pub. No.: US 2026/0079178 A1
(43) Pub. Date: Mar. 19, 2026

(54) CHIP SOCKET ASSEMBLY FOR SEMICONDUCTOR CHIP TESTING AND SEMICONDUCTOR CHIP TESTING APPARATUS INCLUDING THE SAME

(71) Applicant: TSE CO., LTD., Cheonan-si (KR)

(72) Inventors: Bo Hyun KIM, Cheonan-si (KR); Hae Guk CHO, Cheonan-si (KR); Gi Nam GIL, Cheonan-si (KR)

(73) Assignee: TSE CO., LTD., Cheonan-si (KR)

(21) Appl. No.: 19/323,285

(22) Filed: Sep. 9, 2025

(30) Foreign Application Priority Data
Sep. 13, 2024 (KR) 10-2024-0125955
Nov. 28, 2024 (KR) 10-2024-0173472

(51) Int. Cl. G01R 1/04; G01R 31/28

(52) U.S. Cl. CPC G01R 1/0466; G01R 31/2863

(57) ABSTRACT

Disclosed are a chip socket assembly for semiconductor chip testing and a semiconductor chip testing apparatus including the same. The chip socket assembly includes a chip guide member having a chip guide hole through which a chip having a plurality of bumps and a plurality of pads formed on one surface thereof is inserted and guided, a bump guide member having at least one bump guide hole configured to guide the positions of at least some of the bumps and at least one pad exposure hole configured to expose at least some of the pads, an intermediate fastening member having an opening configured to expose at least a part of the one surface of the chip on which the bumps and the pads are formed, and a chip socket substrate provided on one surface thereof with a plurality of probes configured to contact at least some of the pads.

### CROSS REFERENCE TO RELATED APPLICATION

The present application claims priority to Korean Patent Application Nos. 10-2024-0125955 and 10-2024-0173472, filed Sep. 13, 2024 and Nov. 28, 2024 respectively, the entire contents of which are incorporated herein for all purposes by this reference.

### BACKGROUND OF THE INVENTION

### 1. Field of the Invention

The present invention relates to a mechanism and apparatus for testing semiconductor devices/electronic components, and more particularly to a chip socket assembly for semiconductor chip testing and an apparatus including the same.

### 2. Description of the Related Art

Semiconductor devices (e.g., semiconductor chips) formed by densely integrating fine electronic circuits require testing during and after a manufacturing process to ensure that the electronic circuits function properly. For example, the electrical characteristics of semiconductor devices may be tested using a socket apparatus for semiconductor testing. In inspecting the electrical characteristics of semiconductor devices using the socket apparatus for semiconductor testing, conductive terminals (i.e., probes) of the socket and conductive terminals of a semiconductor device need to be connected to each other in an aligned state.

However, with the advancement of semiconductor technology, the size and interval (pitch) of electrode pads (terminals) of a semiconductor device are becoming smaller, making it increasingly difficult to connect probes of a socket apparatus for testing and the electrode pads of the semiconductor device to each other in an accurately aligned state. For example, in a next-generation semiconductor chip, the pad pitch is expected to decrease to approximately 65 μm or less, necessitating the development of a test solution capable of addressing such a fine pitch.

Parts of the socket apparatus are manufactured with machining tolerances, and the semiconductor devices are also manufactured with predetermined size tolerances. Therefore, it is necessary to design the size of the main area of the socket apparatus with a certain margin, taking into account the size tolerance range of the semiconductor devices. Due to these tolerances, it may be difficult to secure a sufficiently small alignment tolerance corresponding to the fine electrode pitch of the semiconductor devices. Furthermore, since the reference for aligning the formation (placement) positions of the probes of the socket apparatus and the reference for aligning the parts of the socket apparatus and the semiconductor device are different from each other, it may be even more difficult to align the positions of the probes and the positions of the pads.

Therefore, there is a need for development of an apparatus and technology capable of reducing the connection alignment tolerance for (error) electrical testing in accordance with the fine electrode pitch of a semiconductor device while overcoming the above problems.

### SUMMARY OF THE INVENTION

It is an object of the present invention to provide a chip socket assembly for semiconductor chip testing capable of reducing the tolerance (error) of connection alignment for electrical testing in response to the miniaturization of the electrode (pad) pitch of a semiconductor chip (device).

It is another object of the present invention to provide a chip socket assembly for semiconductor chip testing capable of improving the alignment accuracy of semiconductor chips by adopting a bump guide function.

It is another object of the present invention to provide a chip socket assembly for semiconductor chip testing capable of improving alignment accuracy between probes and pads by applying a plurality of alignment pins disposed on a chip socket substrate as a coordinate reference for probe bonding and also as an alignment reference for semiconductor devices.

It is another object of the present invention to provide a semiconductor chip testing apparatus including the chip socket assembly for semiconductor chip testing.

The objects of the present invention are not limited to the above objects, and other unmentioned objects will be understood by those skilled in the art based on the following description.

In accordance with one aspect of the present invention, the above and other objects can be accomplished by the provision of a chip socket assembly for semiconductor chip testing, the chip socket assembly including a chip guide member having a chip guide hole through which a chip having a plurality of bumps and a plurality of pads formed on one surface thereof is inserted and guided, a bump guide member disposed in contact with or adjacent to the chip guide member, the bump guide member having at least one bump guide hole configured to guide the positions of at least some of the plurality of bumps and at least one pad exposure hole configured to expose at least some of the plurality of pads, an intermediate fastening member disposed opposite the chip guide member with the bump guide member interposed therebetween, the intermediate fastening member having an opening configured to expose at least a part of the one surface of the chip on which the plurality of bumps and the plurality of pads are formed, and a chip socket substrate coupled to the intermediate fastening member, the chip socket substrate being provided on one surface thereof with a plurality of probes configured to contact at least some of the plurality of pads.

The bump guide member may be coupled to the chip guide member, and the intermediate fastening member may be coupled to the chip guide member with the bump guide member interposed therebetween.

The bump guide member may include a first bump guide hole configured to guide the positions of first group bumps, among the plurality of bumps, while exposing the first group bumps.

The bump guide member may further include a second bump guide hole configured to guide the positions of second group bumps, among the plurality of bumps, while exposing the second group bumps, and the second bump guide hole may be disposed spaced apart from the first bump guide hole.

The bump guide member may be an insulating film member.

The bump guide member may include at least one of a polymer material and a ceramic material.

The intermediate fastening member may be provided with a plurality of fastening elements elastically movable upward and downward, and the chip guide member may be provided with a plurality of fastening holes to which the plurality of fastening elements is fastened.

Each of the plurality of fastening elements may include a plunger.

A coupling structure of the chip guide member and the bump guide member may be configured to elastically move upward and downward relative to the intermediate fastening member coupled thereto.

A plurality of alignment pins may be disposed on one surface of the chip socket substrate on which the plurality of probes is formed, and the plurality of alignment pins may be used as an alignment reference when the chip guide member, the bump guide member, and the intermediate fastening member are assembled to the chip socket substrate.

Each of the chip guide member, the bump guide member, and the intermediate fastening member may be provided with a plurality of alignment guide holes into which the plurality of alignment pins is inserted.

The plurality of probes may be formed on the one surface of the chip socket substrate by bonding using the plurality of alignment pins as a coordinate reference.

The chip may include, for example, a high bandwidth memory (HBM).

In accordance with another aspect of the present invention, there is provided a semiconductor chip testing apparatus including the chip socket assembly.

### BRIEF DESCRIPTION OF THE DRAWINGS

FIG. 1 is an exploded perspective view illustrating a chip socket assembly for semiconductor chip testing according to an embodiment of the present invention;

FIG. 2 is a plan view exemplarily showing a chip applicable to the chip socket assembly for semiconductor chip testing according to the embodiment of the present invention;

FIGS. 3 and 4 are sectional views exemplarily showing a part of the chip applicable to the chip socket assembly for semiconductor chip testing according to the embodiment of the present invention;

FIG. 5 is a plan view showing a chip socket substrate applicable to the chip socket assembly for semiconductor chip testing according to the embodiment of the present invention;

FIG. 6 is a plan view showing a chip guide member and a bump guide member applicable to the chip socket assembly for semiconductor chip testing according to the embodiment of the present invention;

FIG. 7 is a plan view showing an intermediate fastening member applicable to the chip socket assembly for semiconductor chip testing according to the embodiment of the present invention;

FIGS. 8 to 10 are sectional views exemplarily showing a process of guiding a chip and seating the chip on a seating portion using the chip socket assembly for semiconductor chip testing according to the embodiment of the present invention;

FIGS. 11 and 12 are sectional views exemplarily showing a process of seating a chip on the seating portion using the chip socket assembly for semiconductor chip testing according to the embodiment of the present invention;

FIG. 13 is an exploded perspective view illustrating a chip socket assembly for semiconductor chip testing according to a comparative example;

FIG. 14 is a plan view showing a chip socket substrate of the chip socket assembly according to the comparative example of FIG. 13;

FIG. 15 is a plan view showing a chip guide plate of the chip socket assembly according to the comparative example of FIG. 13; and

FIGS. 16 and 17 are sectional views illustrating a process of seating a chip on a seating portion using the chip socket assembly for semiconductor chip testing according to the comparative example and problems thereof.

### DETAILED DESCRIPTION OF THE PREFERRED EMBODIMENTS

Hereinafter, embodiments of the present invention will be described in detail with reference to the accompanying drawings.

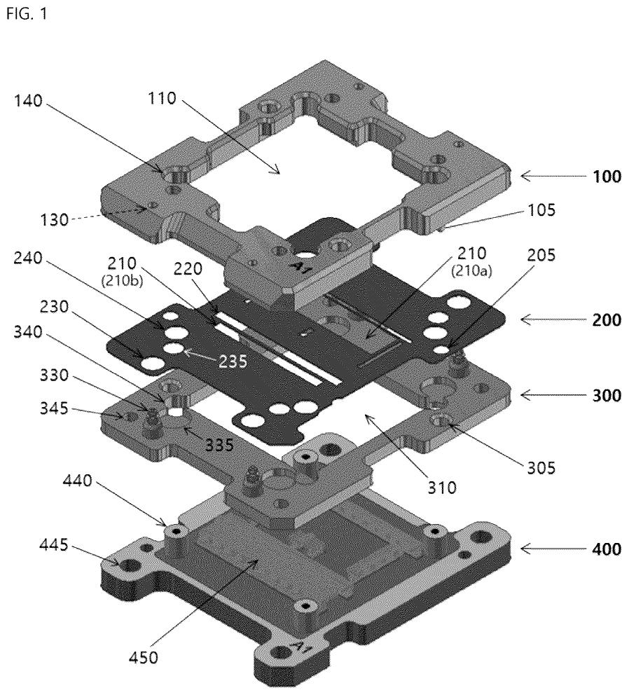

FIG. 1 is an exploded perspective view illustrating a socket assembly for semiconductor chip testing chip according to an embodiment of the present invention.

Referring to FIG. 1, the chip socket assembly for semiconductor chip testing according to the embodiment of the present invention may include a chip guide member 100, a bump guide member 200, an intermediate fastening member 300, and a chip socket substrate 400.

The chip guide member 100 may have a chip guide hole 110 through which a chip (semiconductor chip) is inserted and guided. The chip may be a chip having a plurality of bumps and a plurality of pads (electrode pads) formed on one side surface thereof. The chip may also be referred to as a kind of die. The chip may, for example, have a quadrangular shape, and the chip guide hole 110 may have a shape into which the chip can be inserted. The chip guide member 100 may have a plate shape or a frame shape surrounding the chip guide hole 110. The chip guide member 100 may serve to primarily guide and align the chip and to seat the chip on the bump guide member 200.

The bump guide member 200 may be disposed opposite the chip guide member 100. The bump guide member 200 may be disposed in contact with or adjacent to the chip guide member 100. The bump guide member 200 may be disposed on a lower surface of the chip guide member 100. The bump guide member 200 may have at least one bump guide hole 210 configured to guide the positions of at least some of the plurality of bumps and at least one pad exposure hole 220 configured to expose at least some of the plurality of pads. One or more bump guide holes 210 may be formed, and one or more pad exposure holes 220 may be formed. The bump guide member 200 may have a relatively thin film shape or a plate shape. The bump guide member 200 may serve to secondarily guide and align the chip by guiding the bumps of the chip using the bump guide hole 210. The chip may be seated on the bump guide member 200. The bump guide member 200 may be an insulator.

The intermediate fastening member 300 may be located opposite the chip guide member 100 with the bump guide member 200 interposed therebetween. Therefore, the bump guide member 200 may be disposed between the chip guide member 100 and the intermediate fastening member 300. The intermediate fastening member 300 may be disposed under the bump guide member 200, i.e., on a lower side thereof. The intermediate fastening member 300 may have an opening 310 configured to expose at least a part of one surface of the chip on which the plurality of bumps and the plurality of pads are formed. The opening 310 may, for example, have a roughly quadrangular shape. The intermediate fastening member 300 may have a plate shape or a frame shape surrounding the opening 310. The intermediate fastening member 300 may be coupled to at least one of the chip guide member 100 and the bump guide member 200.

In an example, the bump guide member 200 may be coupled to the chip guide member 100, and the intermediate fastening member 300 may be coupled to the chip guide member 100 with the bump guide member 200 interposed therebetween. The bump guide member 200 may be coupled to the chip guide member 100 in contact with the lower surface of the chip guide member 100. A coupling structure (first coupling structure) in which the chip guide member 100 and the bump guide member 200 are coupled to each other may be coupled to the intermediate fastening member 300. The intermediate fastening member 300 may be coupled to a lower surface of the first coupling structure.

The chip socket substrate 400 may be coupled to the intermediate fastening member 300. The chip socket substrate 400 may be coupled to a lower surface of the intermediate fastening member 300. A coupling structure (second coupling structure) in which the chip guide member 100, the bump guide member 200, and the intermediate fastening member 300 are coupled to each other may be coupled to the chip socket substrate 400. The chip socket substrate 400 may include a printed circuit board (PCB). The chip socket substrate 400 may serve to electrically connect the chip to a test board. In addition, the chip socket substrate 400 may serve to convert a fine electrode pitch of the chip into a normal pitch of the test board. A plurality of probes 450 may be formed (disposed) on one surface (upper surface) of the chip socket substrate 400 so as to contact at least some of the plurality of pads formed on the chip. The plurality of probes 450 may serve to electrically connect the chip to the chip socket substrate 400. In other words, the chip and the PCB of the chip socket substrate 400 may be electrically connected to each other via the plurality of probes 450.

The intermediate fastening member 300 may serve to form a predetermined gap between the chip socket substrate 400 and the bump guide member 200. At least some of the plurality of probes 450 may be inserted into the opening 310 of the intermediate fastening member 300. All of the plurality of probes 450 may be disposed in an area corresponding to the opening 310. The plurality of probes 450 may be connected to the pads (electrode pads) of the chip through the opening 310.

In accordance with an embodiment, the bump guide member 200 may include a first bump guide hole 210a configured to guide the positions of first group bumps, among the plurality of bumps, while exposing the first group bumps. The first bump guide hole 210a may serve to guide the first group bumps while exposing the same. Among the first group bumps, two or more bumps located at the edge (outer periphery) may come into contact with the part of the bump guide member 200 corresponding to the boundary of the first bump guide hole 210a, whereby the positions of the first group bumps may be adjusted and thus the position of the chip may be adjusted. In other words, the positions of the first group bumps may be adjusted as the first group bumps are introduced into the first bump guide hole 210a, and therefore the position of the chip may be adjusted.

In addition, the bump guide member 200 may further include a second bump guide hole 210b configured to guide the positions of second group bumps, among the plurality of bumps, while exposing the second group bumps. The second bump guide hole 210b may be disposed spaced apart from the first bump guide hole 210a. The second bump guide hole 210b may serve to guide the second group bumps while exposing the same. Among the second group bumps, two or more bumps located at the edge (outer periphery) may come into contact with the part of the bump guide member 200 corresponding to the boundary of the second bump guide hole 210b, whereby the positions of the second group bumps may be adjusted and thus the position of the chip may be adjusted. In other words, the positions of the second group bumps may be adjusted as the second group bumps are introduced into the second bump guide hole 210b, and therefore the position of the chip may be adjusted.

When the position of the chip is finely adjusted (guided) using the first bump guide hole 210a and the second bump guide hole 210b, which are spaced apart from each other, it may be possible to more accurately and precisely align the position of the chip. When the position of the chip is guided in a plurality of areas using two or more bump guide holes, the position adjustment characteristics of the chip may be further improved. However, in some cases, only one bump guide hole may be used, or three or more bump guide holes may be used. The number and disposition of the bump guide holes 210 and the pad exposure holes 220 shown herein are merely examples and may be variously changed.

In accordance with an embodiment, the bump guide member 200 may be an insulating film member. In this case, the thickness of the bump guide member 200 may be approximately 10 mm or less, as a non-limiting example. The bump guide member 200 may include at least one of a polymer material and a ceramic material. The bump guide member 200 may be made of a polymer material or a ceramic material. As a non-limiting example, the polymer material may include polyimide (PI) and polytetrafluoroethylene (PTFE; Teflon). It may be preferable for the bump guide member 200 to have appropriate strength and elasticity. The openings, such as the bump guide holes 210 and the pad exposure holes 220, may be precisely formed, for example, through laser machining. Alternatively, the bump guide member 200 may be precisely manufactured through a microelectromechanical system (MEMS) process.

In accordance with an embodiment, the intermediate fastening member 300 may be provided with a plurality of fastening elements 330 elastically movable upward and downward, and the chip guide member 100 may be provided with a plurality of fastening holes 130 to which the plurality of fastening elements 330 is fastened. Each of the fastening elements 330 may be inserted into a lower part of a corresponding one of the fastening holes 130 and fastened to the fastening hole 130. In addition, the bump guide member 200 may include through-holes 230, and the fastening elements 330 may be fastened to the fastening holes 130 through the through-holes 230.

Each of the plurality of fastening elements 330 may include, for example, a plunger. The plunger may be a member that is elastically movable upward and downward. An elastic member, such as a spring, may be provided in the plunger. In an example, the plunger may be a fixed plunger, but the present invention is not limited thereto.

The intermediate fastening member 300 and the chip guide member 100 may be coupled to each other via the plurality of fastening elements 330, and the chip guide member 100 may elastically move upward and downward relative to the intermediate fastening member 300. More the coupling specifically, structure (first coupling structure) in which the chip guide member 100 and the bump guide member 200 are coupled to each other may be coupled to the intermediate fastening member 300 via the plurality of fastening elements 330, and the first coupling structure may elastically move upward and downward relative to the intermediate fastening member 300 coupled thereto. In the state in which the first coupling structure is coupled to the intermediate fastening member 300, the first coupling structure may be slightly spaced apart from a main body of the intermediate fastening member 300. That is, in the state in which the first coupling structure is coupled to the intermediate fastening member 300, the bump guide member 200 may be slightly spaced apart from the main body of the intermediate fastening member 300. At this time, as the chip guide member 100 is pressed downward from above, the first coupling structure may move downward, and the bump guide member 200 may move closer to or come into contact with the intermediate fastening member 300. When the force pressing the chip guide member 100 downward is removed, the distance between the bump guide member 200 and the intermediate fastening member 300 may increase. In this way, connection and disconnection between the pads of the chip and the probes 450 may be controlled. However, the detailed configuration of the plurality of fastening elements 330 and related operating mechanisms are exemplary and may vary depending on the circumstances.

In accordance with a specific embodiment, a plurality of guide pins 105 may be disposed on the lower surface of the chip guide member 100, a plurality of through-guide-holes 205 may be formed in the bump guide member 200, and a plurality of guide holes 305 may be formed in the intermediate fastening member 300. In addition, a plurality of through-holes 235 may be formed in the bump guide member 200, and a plurality of insertion holes corresponding to the plurality of through-holes 235 may be formed in the chip guide member 100. In the state in which the bump guide member 200 is disposed on the lower surface of the chip guide member 100 such that the guide pins 105 pass through the guide holes 205, fastening members, such as bolts, may be inserted into the through-holes 235 and the insertion holes from under the through-holes 235. In this way, the chip guide member 100 and the bump guide member 200 may be coupled to each other. Lower parts of the fastening members, such as bolts, may be inserted into recesses 335 formed in the intermediate fastening member 300. After the chip guide member 100 and the bump guide member 200 are coupled to form the first coupling structure, the intermediate fastening member 300 may be coupled to the first coupling structure. At this time, the guide pins 105 may be inserted into the guide holes 305. In addition, the fastening elements 330 may be fastened to the fastening holes 130 through the through-holes 230.

In accordance with an plurality of alignment pins 440 may be disposed on one surface of the chip socket substrate 400 having the plurality of probes 450 formed thereon. The alignment pins 440 may be provided in three or more or four or more. The plurality of alignment pins 440 may be disposed outside the plurality of probes 450. Each of the plurality of alignment pins 440 may have a columnar shape. For example, each of the plurality of alignment pins 440 may have a shape such as a cylinder, a quadrangular column, or a polygonal column. The plurality of alignment pins 440 may be manufactured using the microelectromechanical system (MEMS) process or a general machining process. When the MEMS process is used, precision of the plurality of alignment pins 440 may be further improved.

The plurality of alignment pins 440 may be used as an alignment reference when the chip guide member 100, the bump guide member 200, and the intermediate fastening member 300 are assembled to the chip socket substrate 400. When the coupling structure (second coupling structure) in which the chip guide member 100, the bump guide member 200, and the intermediate fastening member 300 are coupled to each other is coupled to the chip socket substrate 400, the plurality of alignment pins 440 may be used as the alignment reference. In this regard, pluralities of alignment guide holes 140, 240, and 340, into which the plurality of alignment pins 440 is inserted, may be formed in the chip guide member 100, the bump guide member 200, and the intermediate fastening member 300, respectively. A plurality of first alignment guide holes 140 may be formed in the chip guide member 100, a plurality of second alignment guide holes 240 may be formed in the bump guide member 200, and a plurality of third alignment guide holes 340 may be formed in the intermediate fastening member 300. As the plurality of alignment pins 440 is inserted into the pluralities of first to third alignment guide holes 140, 240, and 340, the chip socket substrate 400 and the second coupling structure may be aligned with each other. Therefore, the assembly tolerance between the parts may be reduced.

The plurality of probes 450 may be formed on one surface of the chip socket substrate 400 by bonding using the plurality of alignment pins 440 as a coordinate reference. In other words, the plurality of alignment pins 440 may be used as the coordinate reference in a bonding process in which the plurality of probes 450 is bonded to one surface of the chip socket substrate 400. Therefore, the plurality of alignment pins 440 may be used as a reference for determining the bonding positions of the plurality of probes 450 and as an alignment reference for aligning the chip guide member 100, the bump guide member 200, and the intermediate fastening member 300 on the chip socket substrate 400. The reference for bonding the plurality of probes 450 and the reference for determining the alignment position of the chip may be the same. In this way, since the coordinate reference for probe bonding and the reference for aligning the parts of the chip socket assembly and the semiconductor chip may be the same, the alignment accuracy between the probes 450 and the pads of the chip may be greatly improved.

Additionally, a plurality of through-holes 445 may be provided in the chip socket substrate 400, and a plurality of insertion holes 345 corresponding to the plurality of through-holes 445 may be provided in the intermediate fastening member 300. In a non-limiting example, after the second coupling structure is disposed on the chip socket substrate 400, fastening members, such as bolts, may be inserted into the insertion holes 345 through the through-holes 445 from under the chip socket substrate 400 to fasten the chip socket substrate 400 and the intermediate fastening member 300 to each other.

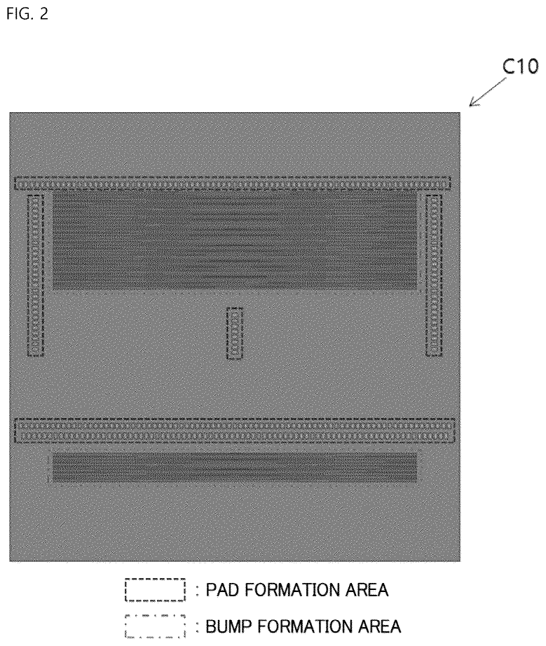

FIG. 2 is a plan view exemplarily showing a chip C10 applicable to the chip socket assembly for semiconductor chip testing according to the embodiment of the present invention.

Referring to FIG. 2, a plurality of bumps and a plurality of pads (electrode pads) may be formed on one surface (e.g., a lower surface) of the chip C10. At least one bump formation area and at least one pad formation area may be provided on one surface of the chip C10. A plurality of bumps may be arranged in the bump formation area so as to form an array, and a plurality of pads may be arranged in the pad formation area so as to form an array. The number and position of the bump formation areas and the pad formation areas shown in FIG. 2 are merely exemplary and may be variously changed.

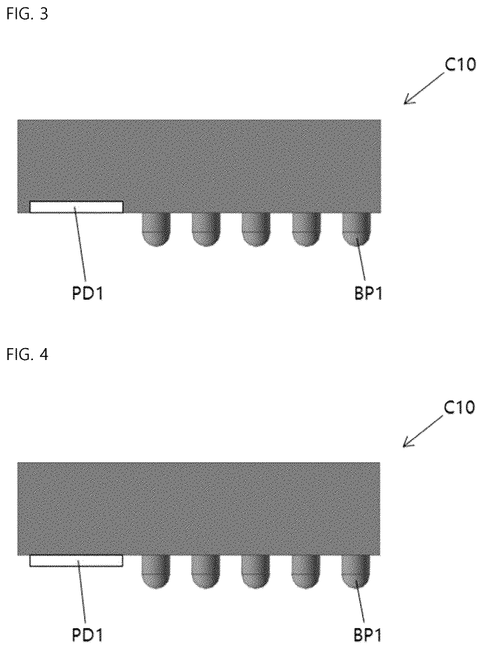

FIGS. 3 and 4 are sectional views exemplarily showing a part of the chip C10 applicable to the chip socket assembly for semiconductor chip testing according to the embodiment of the present invention.

Referring to FIGS. 3 and 4, a bump BP1 may be disposed so as to protrude toward one surface (e.g., the lower surface) of the chip C10. The protrusion length of the bump BP1 may be tens of nm or more, several μm or more, or tens of μm or more, as a non-limiting example. A pad PD1 may be formed so as to be depressed in one surface of the chip C10, as shown in FIG. 3, or may be formed so as to protrude from one surface of the chip C10, as shown in FIG. 4. Even in the case of FIG. 4, the protrusion height of the pad PD1 may be less than that of the bump BP1. The bump BP1 may be of a general bump type or a ball type.

The chip C10 illustrated in FIGS. 2 to 4 may be a high bandwidth memory (HBM) or may include an HBM, as a non-limiting example. In the case of a next-generation HBM chip, a pad pitch is expected to be reduced to approximately 65 μm or less. The chip socket assembly according to the embodiment of the present invention may have a configuration and characteristics that can provide a precise and accurate test solution in response to the fine pitch of the next-generation HBM chip. However, the type of the chip applicable to the embodiment of the present invention is not limited to HBM and may be variously changed.

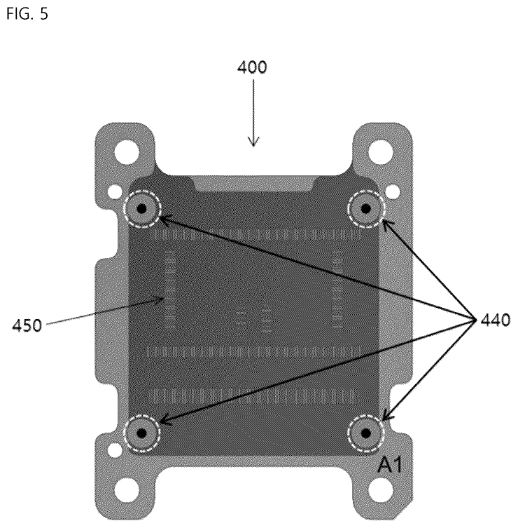

FIG. 5 is a plan view showing a chip socket substrate 400 applicable to the chip socket assembly for semiconductor chip testing according to the embodiment of the present invention.

Referring to FIG. 5, the chip socket substrate 400 may have the same configuration as described with reference to FIG. 1. A plurality of probes 450 may be formed (disposed) on one surface (upper surface) of the chip socket substrate 400. In addition, a plurality of alignment pins 440 may be provided on one surface of the chip socket substrate 400 having the plurality of probes 450 formed thereon. The plurality of alignment pins 440 may be disposed outside the plurality of probes 450. The plurality of probes 450 may be formed on one surface of the chip socket substrate 400 by bonding using the plurality of alignment pins 440 as a coordinate reference. That is, the plurality of alignment pins 440 may be used as the coordinate reference in a bonding process in which the plurality of probes 450 is bonded to one surface of the chip socket substrate 400.

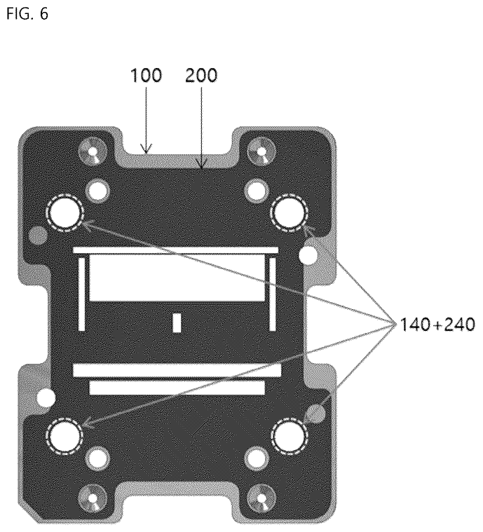

FIG. 6 is a plan view showing a chip guide member 100 and a bump guide member 200 applicable to the chip socket assembly for semiconductor chip testing according to the embodiment of the present invention.

Referring to FIG. 6, a coupling structure (first coupling structure) in which the chip guide member 100 and the bump guide member 200 are coupled to each other is shown. A plurality of first alignment guide holes 140 may be formed in the chip guide member 100, and a plurality of second alignment guide holes 240 may be formed in the bump guide member 200.

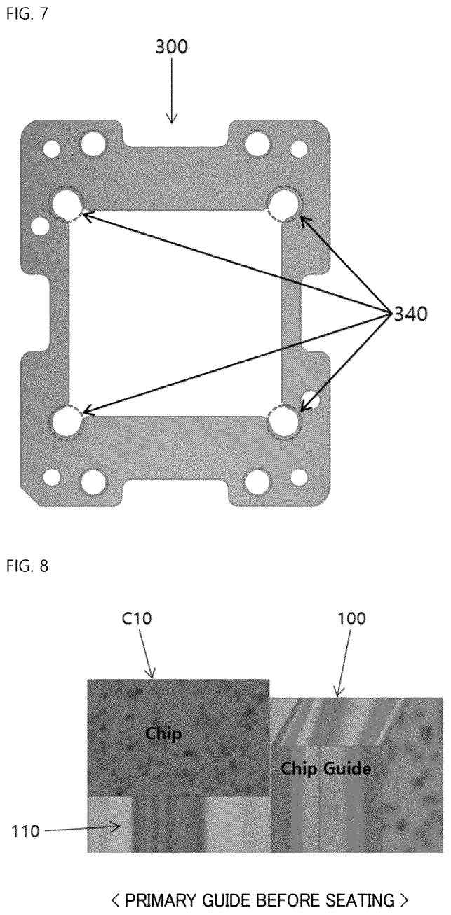

FIG. 7 is a plan view showing an intermediate fastening member 300 applicable to the chip socket assembly for semiconductor chip testing according to the embodiment of the present invention.

Referring to FIG. 7, a plurality of third alignment guide holes 340 may be formed in the intermediate fastening member 300.

As described above with reference to FIGS. 5 to 7, after bonding the plurality of probes 450 to the chip socket substrate 400 based on the plurality of alignment pins 440, the chip guide member 100, the bump guide member 200, and the intermediate fastening members 300 may be assembled to the chip socket substrate 400 based on the same plurality of alignment pins 440. For example, a coupling structure (second coupling structure) in which the chip guide member 100, the bump guide member 200, and the intermediate fastening member 300 are coupled to each other may be coupled to the chip socket substrate 400 based on the plurality of alignment pins 440. In this way, since the coordinate reference for probe bonding and the assembly reference for parts of the chip socket assembly may be the same, the connection (contact) accuracy between the probes 450 and the pads of the chip may be significantly improved.

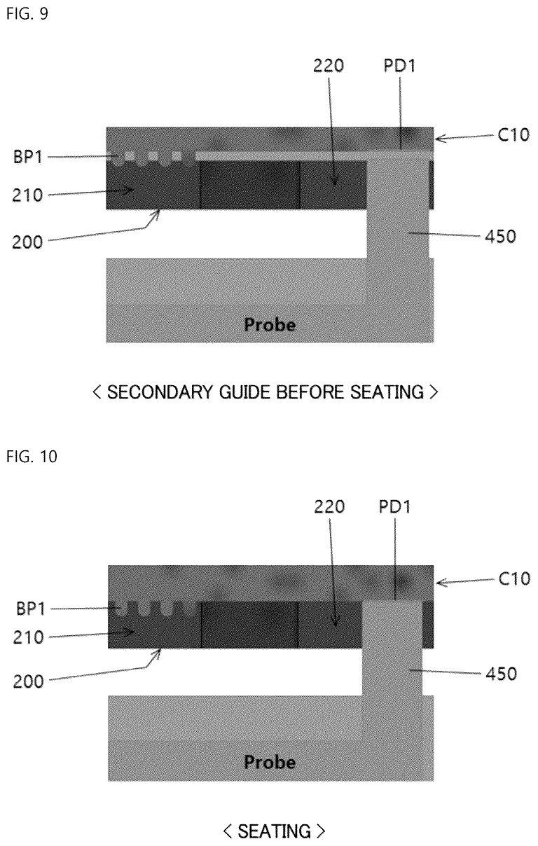

FIGS. 8 to 10 are sectional views exemplarily showing a process of guiding a chip and seating the chip on a seating portion using the chip socket assembly for semiconductor chip testing according to the embodiment of the present invention.

Referring to FIG. 8, the chip C10 may be inserted into the chip guide hole 110 of the chip guide member 100, whereby the chip may be primarily guided and aligned. The chip guide member 100 may guide the chip C10 based on the outer periphery of the chip C10.

Referring to FIG. 9, the bumps BP1 of the chip C10 may be introduced into the bump guide hole 210 of the bump guide member 200, whereby the positions thereof may be precisely guided, and as a result, the position of the chip C10 may be secondarily guided and aligned. Among the bumps BP1, two or more bumps located at the edge (outer periphery) may come into contact with the part of the bump guide member 200 corresponding to the boundary of the bump guide hole 210, whereby the positions of the bumps BP1 may be adjusted and thus the position of the chip C10 may be adjusted. In other words, the position of the chip C10 may be precisely adjusted based on the positions of the bumps BP1.

Referring to FIG. 10, the chip C10 may be seated on the bump guide member 200. The probe 450 may come into contact with the pad PD1 of the chip C10 through the pad exposure hole 220. The shape of the probe 450 shown herein is exemplary and may vary. An end (i.e., tip) of the actual probe 450 may have a width less than that of the pad PD1.

In accordance with an embodiment of the present invention, it is possible to improve the alignment characteristics between the pad PD1 of the chip C10 and the probe 450 by precisely guiding and aligning the position of the chip C10 based on the bump BP1 using the bump guide member 200. In addition, since the position of the probe 450 is also aligned with the position of the bump guide member 200 during assembly of the parts, the alignment characteristics and the contact characteristics between the pad PD1 and the probe 450 may be improved, and the electrical characteristics related thereto may also be improved. Therefore, electrical testing may be easily performed even for a semiconductor chip having a fine pad pitch.

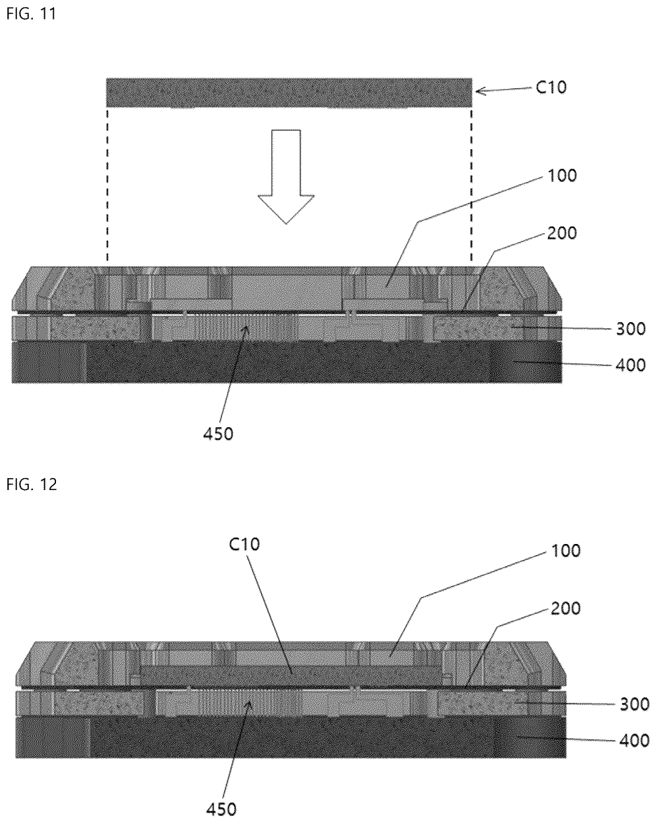

FIGS. 11 and 12 are sectional views exemplarily showing a process of seating a chip on the seating portion using the chip socket assembly for semiconductor chip testing according to the embodiment of the present invention.

Referring to FIGS. 11 and 12, an assembled chip socket assembly may include a chip guide member 100, a bump guide member 200, an intermediate fastening member 300, and a chip socket substrate 400. A plurality of probes 450 may be disposed on the chip socket substrate 400. As a non-limiting example, the chip C10 may be inserted into the chip guide hole of the chip socket assembly using a predetermined picker apparatus (or a pick-and-place apparatus). The chip C10 may be seated on the bump guide member 200.

In accordance with an embodiment of the present invention, a semiconductor chip testing apparatus including a chip socket assembly for semiconductor chip testing according to the above embodiment may be provided. The configuration of the semiconductor chip testing apparatus excluding the chip socket assembly may be identical to the configuration of a general testing apparatus. The chip socket assembly may be applied to a plurality of apparatuses and may be moved while holding a chip (die). In this aspect, the chip socket assembly may also be referred to as a die carrier socket.

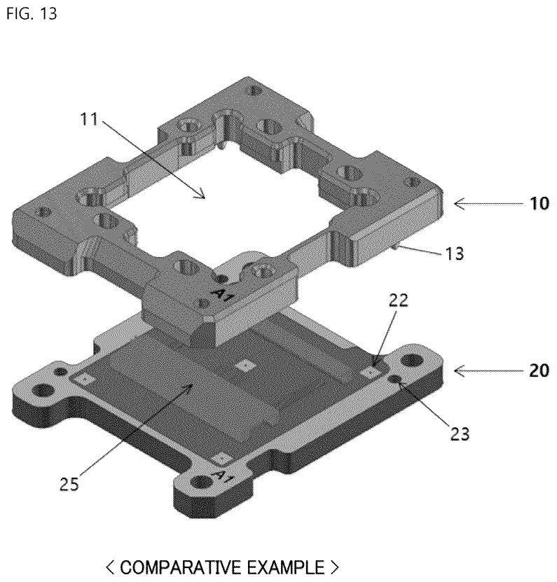

FIG. 13 is an exploded perspective view illustrating a chip socket assembly for semiconductor chip testing according to a comparative example.

Referring to FIG. 13, the chip socket assembly for semiconductor chip testing according to the comparative example may include a chip guide plate 10 and a chip socket substrate 20. The chip guide plate 10 may have a chip guide hole 11 through which a chip is inserted and guided. In addition, a plurality of guide pins 13 may be provided on a lower surface of the chip guide plate 10. A plurality of probes 25 may be disposed on an upper surface of the chip socket substrate 20 so as to contact at least some of a plurality of pads formed on the chip. In addition, a plurality of alignment pads 22 configured to serve as a reference for the bonding positions of the plurality of probes 25 may be disposed on the upper surface of the chip socket substrate 20. In addition, a plurality of guide holes 23 into which the plurality of guide pins 13 of the chip guide plate 10 is inserted may be formed in the chip socket substrate 20.

In the comparative example shown in FIG. 13, alignment between the chip guide plate 10 and the chip socket substrate 20 may be performed based on the guide pins 13 and the guide holes 23. Meanwhile, the bonding positions of the plurality of probes 25 may be determined using the plurality of alignment pads 22 as a coordinate reference. As such, since the reference for determining the bonding positions of the plurality of probes 25 and the reference for aligning the chip guide plate 10 and the chip socket substrate 20 are different from each other, the alignment accuracy between the pads of the chip and the probes 25 may be reduced. In addition, since the chip is guided only using the outer periphery thereof in the comparative example, it may be difficult to precisely and accurately align the position of the chip with respect to the probes due to machining tolerance of the parts and manufacturing tolerance of the chip.

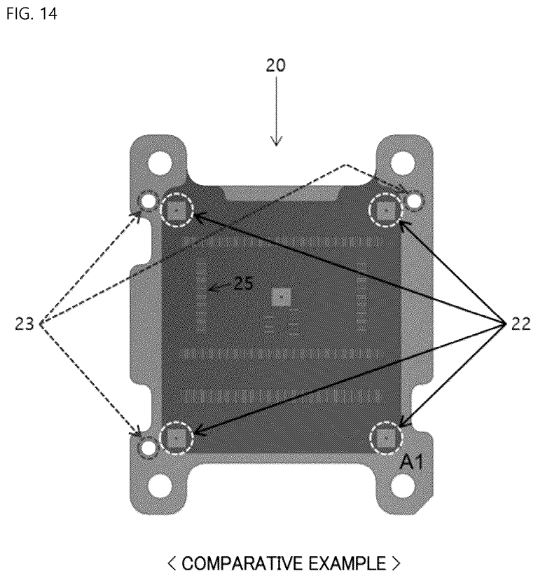

FIG. 14 is a plan view showing a chip socket substrate 20 of the chip socket assembly according to the comparative example of FIG. 13.

Referring to FIG. 14, the chip socket substrate 20 of the chip socket assembly according to the comparative example may have the same configuration as described with reference to FIG. 13. A plurality of probes 25 may be disposed on an upper surface of the chip socket substrate 20. A plurality of alignment pads 22 configured to serve as a reference for the bonding positions of the plurality of probes 25 may be disposed on the upper surface of the chip socket substrate 20. In addition, a plurality of guide holes 23 into which the plurality of guide pins 13 (FIG. 13) of the chip guide plate 10 (FIG. 13) is inserted may be formed in the chip socket substrate 20.

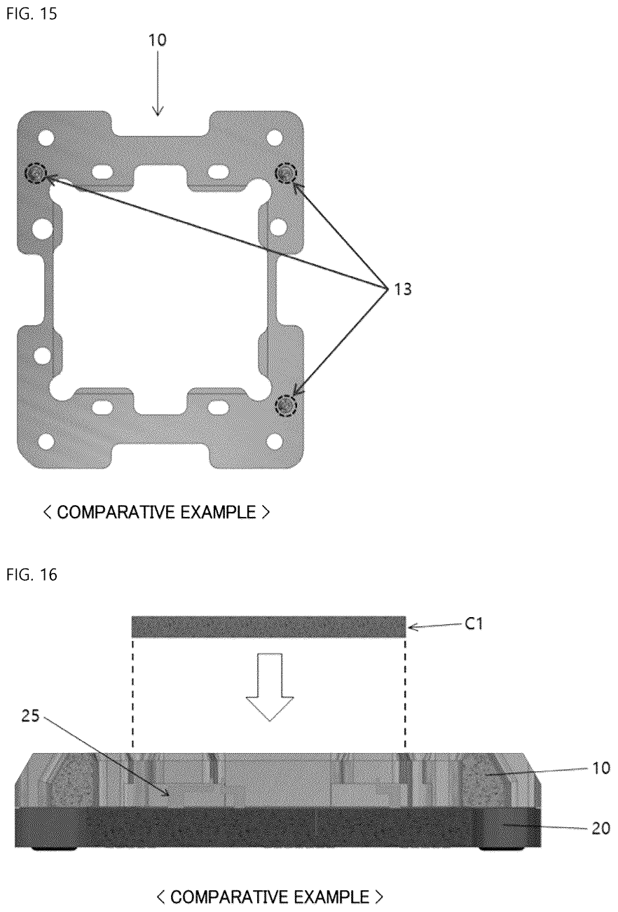

FIG. 15 is a plan view showing a chip guide plate 10 of the chip socket assembly according to the comparative example of FIG. 13.

Referring to FIG. 15, the chip guide plate 10 of the chip socket assembly according to the comparative example may include a plurality of guide pins 13 provided on a lower surface thereof.

In the comparative example, the plurality of probes 25 can be bonded to the chip socket substrate 20 using the plurality of alignment pads 22 as a coordinate reference.

After the plurality of probes 25 is bonded, the chip guide plate 10 and the chip socket substrate 20 may be assembled based on the guide pins 13 and the guide holes 23. As such, since the reference (position reference) during the bonding of the plurality of probes 25 and the reference (position reference) during the assembly of the parts are different from each other, the contact alignment between the probes 25 and the pads of the chip may be incorrect after assembly.

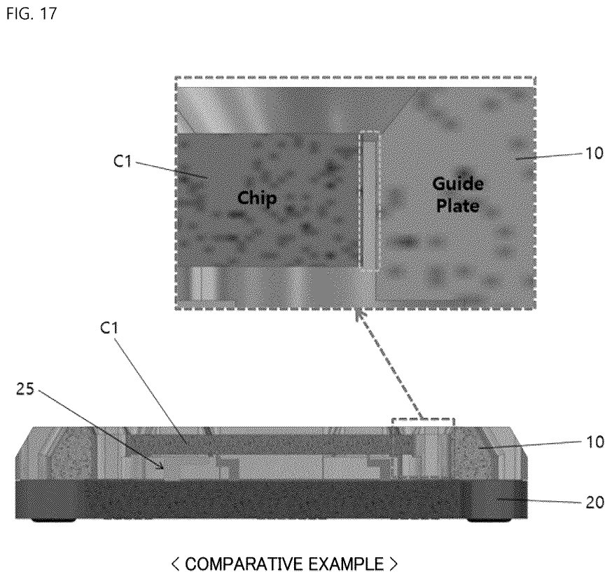

FIGS. 16 and 17 are sectional views illustrating a process of seating a chip on a seating portion using the chip socket assembly for semiconductor chip testing according to the comparative example and problems thereof.

Referring to FIGS. 16 and 17, the chip socket assembly according to the comparative example may include a chip guide plate 10 and a chip socket substrate 20 assembled thereto. A plurality of probes 25 may be disposed on the chip socket substrate 20. The chip C1 may be inserted into a chip guide hole of the chip socket assembly.

In the comparative example, the chip C1 is guided based only on the outer periphery of the chip C1. In this case, an alignment problem may occur depending on the size (outer periphery size) of the chip C1. In particular, if the size of the chip C1 is at or near the minimum value of an allowable tolerance, a relatively large gap may occur between the chip C1 and the chip guide plate 10 in the chip guide hole, which is designed with sufficient clearance. As a result, an alignment problem may occur between the pads of the chip C1 and the probes 25. The contact between the pads of the chip C1 and the probes 25 may be unstable, making it difficult to perform accurate electrical testing.

In accordance with the embodiment of the present invention, however, it is possible to overcome the problems and limitations of the chip socket assembly according to the comparative examples described with reference to FIGS. 13 to 17.

In accordance with the embodiments of the present invention described above, it is possible to implement a chip socket assembly for semiconductor chip testing capable of reducing a tolerance (error) of connection alignment for electrical testing in response to the miniaturization of the electrode (pad) pitch of a semiconductor chip (device).

In accordance with an embodiment of the present invention, it is possible to implement a chip socket assembly for semiconductor chip testing capable of improving the alignment accuracy of a semiconductor chip by adopting a bump guide function. Since it is possible to align the chip by primarily guiding the outer periphery of the semiconductor chip and to precisely align the chip by secondarily guiding the bump group of the semiconductor chip using the bump guide member, the alignment accuracy of the chip with respect to the test probes may be greatly improved.

Furthermore, in accordance with an embodiment of the present invention, it is possible to implement a chip socket assembly for semiconductor chip testing capable of improving the alignment accuracy between the probes and the pads by applying the plurality of alignment pins disposed on the chip socket substrate as a coordinate reference for probe bonding and also as a reference for aligning the semiconductor device. Since the coordinate reference for probe bonding and the reference for aligning the parts of the chip socket assembly and the semiconductor chip may be the same, the alignment accuracy between the probes and the pads may be significantly improved.

When the chip socket assembly according to the embodiments of the present invention is adopted, it is possible to implement a semiconductor chip testing apparatus capable of facilitating electrical characteristic evaluation of a next-generation semiconductor chip (device) having a fine electrode (pad) pitch.

However, the effects of the present invention are not limited to the above effects, and may be variously expanded without departing from the technical ideas and scope of the present invention.

What is claimed is:

1. A chip socket assembly for semiconductor chip testing, the chip socket assembly comprising:
a chip guide member having a chip guide hole through which a chip having a plurality of bumps and a plurality of pads formed on one surface thereof is inserted and guided;
a bump guide member disposed in contact with or adjacent to the chip guide member, the bump guide member having at least one bump guide hole configured to guide positions of at least some of the plurality of bumps and at least one pad exposure hole configured to expose at least some of the plurality of pads;
an intermediate fastening member disposed opposite the chip guide member with the bump guide member interposed therebetween, the intermediate fastening member having an opening configured to expose at least a part of the one surface of the chip on which the plurality of bumps and the plurality of pads are formed; and
a chip socket substrate coupled to the intermediate fastening member, the chip socket substrate being provided on one surface thereof with a plurality of probes configured to contact at least some of the plurality of pads.

2. The chip socket assembly according to claim 1, wherein
the bump guide member is coupled to the chip guide member, and
the intermediate fastening member is coupled to the chip guide member with the bump guide member interposed therebetween.

3. The chip socket assembly according to claim 1, wherein the bump guide member comprises a first bump guide hole configured to guide positions of first group bumps, among the plurality of bumps, while exposing the first group bumps.

4. The chip socket assembly according to claim 3, wherein
the bump guide member further comprises a second bump guide hole configured to guide positions of second group bumps, among the plurality of bumps, while exposing the second group bumps, and
the second bump guide hole is disposed spaced apart from the first bump guide hole.

5. The chip socket assembly according to claim 1, wherein the bump guide member is an insulating film member.

6. The chip socket assembly according to claim 1, wherein the bump guide member comprises at least one of a polymer material and a ceramic material.

7. The chip socket assembly according to claim 1, wherein
the intermediate fastening member is provided with a plurality of fastening elements elastically movable upward and downward, and
the chip guide member is provided with a plurality of fastening holes to which the plurality of fastening elements is fastened.

8. The chip socket assembly according to claim 7, wherein each of the plurality of fastening elements comprises a plunger.

9. The chip socket assembly according to claim 1, wherein a coupling structure of the chip guide member and the bump guide member is configured to elastically move upward and downward relative to the intermediate fastening member coupled thereto.

10. The chip socket assembly according to claim 1, wherein
a plurality of alignment pins is disposed on one surface of the chip socket substrate on which the plurality of probes is formed, and
the plurality of alignment pins is used as an alignment reference when the chip guide member, the bump guide member, and the intermediate fastening member are assembled to the chip socket substrate.

11. The chip socket assembly according to claim 10, wherein each of the chip guide member, the bump guide member, and the intermediate fastening member is provided with a plurality of alignment guide holes into which the plurality of alignment pins is inserted.

12. The chip socket assembly according to claim 10, wherein the plurality of probes is formed on the one surface of the chip socket substrate by bonding using the plurality of alignment pins as a coordinate reference.

13. The chip socket assembly according to claim 1, wherein the chip comprises a high bandwidth memory (HBM).

14. A semiconductor chip testing apparatus comprising the chip socket assembly according to claim 1.
